(19) United States
(12) Patent Application Publication
(10) Pub. No.: US 2026/0165050 A1
(43) Pub. Date: Jun. 11, 2026

(54) METHOD AND APPARATUS FOR ATOMIC LAYER ETCHING

(71) Applicant: SEMES CO., LTD., Cheonan-si (KR)

(72) Inventors: Dong Young JANG, Cheonan-si (KR); Min Hee HONG, Cheonan-si (KR); Sang Man PARK, Cheonan-si (KR); Sungmin CHOI, Cheonan-si (KR); Kun Hee KO, Cheonan-si (KR); Jeong Sik KIM, Cheonan-si (KR)

(73) Assignee: SEMES CO., LTD., Cheonan-si (KR)

(21) Appl. No.: 19/411,310

(22) Filed: Dec. 7, 2025

(30) Foreign Application Priority Data
Dec. 9, 2024 (KR) 10-2024-0181771

(51) Int. Cl. H01L 21/223; H01J 37/32; H01L 21/3065

(52) U.S. Cl. CPC H10P 32/1204; H01J 37/32357; H01J 37/32633; H01J 37/32724; H10P 50/242; H01J 2237/3341

(57) ABSTRACT

Disclosed is an atomic layer etching method of etching an etching target film by performing a surface modification step and an etching step. The surface modification step includes a surface modification layer formation step of forming a surface modification layer on a surface of the etching target film using radicals and a precursor supply step of adsorbing precursor molecules onto the surface of the etching target film having the surface modification layer. The etching step includes a heat treatment step of thermally treating a substrate having undergone the surface modification step to remove the surface modification layer from the etching target film and a cooling step of cooling the substrate. The surface modification step further includes a plasma treatment step of treating the surface of the etching target film using ions in at least one of sections before the surface modification layer formation step and after the precursor supply step.

### CROSS-REFERENCE TO THE RELATED APPLICATION

The present application claims priority to and the benefit of Korean Patent Application No. 10-2024-0181771, filed on Dec. 9, 2024, in the Korean Intellectual Property Office, the entire disclosure of which is incorporated herein by reference.

### BACKGROUND

### 1. Field

The present disclosure relates to a method and apparatus for atomic layer etching.

### 2. Description of the Related Art

A substrate processing apparatus is generally used to perform a predetermined processing operation on a substrate such as a semiconductor wafer in order to manufacture a semiconductor device. The predetermined processing operation includes a deposition process of forming a predetermined film on a substrate surface, an etching process of forming a predetermined pattern on the film formed on the substrate, and a cleaning process of physically or chemically cleaning the substrate surface.

As the integration density of semiconductor devices increases and the structures of the devices become more complicated, precise control of a substrate processing operation is becoming increasingly important. In response to this demand, an atomic layer etching (ALE) process, which enables precise control of etching thickness on an atomic layer scale, has attracted attention in etching processes.

In an atomic layer etching process, a technique is known in which a surface modification process of forming a surface modification layer on the surface of an etching target film and an etching process of etching the surface modification layer are performed as one cycle, and the cycle is repeated until a target etching thickness is reached. The surface modification process may include a step of supplying a modification gas to form a reaction layer through reaction between the etching target film and the modification gas and a step of adsorbing a precursor onto the surface of the modified reaction layer to facilitate removal in a subsequent etching process. In addition, the etching process may include a step of removing the surface modification layer through heat treatment. The surface modification process and the etching process may be performed in a single chamber or may be respectively performed in separately provided chambers.

Meanwhile, the atomic layer etching process also needs to be more precisely controlled in order to obtain desired process results depending on the application purpose. For example, when the atomic layer etching process is applied to a three-dimensional pattern such as a high aspect ratio pattern, it may be necessary to ensure that etching proceeds at the same etching rate regardless of the position of the pattern, or it may be necessary to differently control the etching rate depending on the pattern position. In addition, in some cases, it is required to control an etching profile into a desired shape. Furthermore, there may be a need for a technique capable of more freely increasing or reducing an etching amount in one cycle.

However, conventional atomic layer etching process technologies may be insufficient to meet such various requirements.

### RELATED ART DOCUMENT

### Patent Document

(Patent Document 1) KR 10-2024-0062157 A (May 9, 2024)

### SUMMARY

An aspect of the present disclosure is to provide a method and apparatus for atomic layer etching capable of more precisely controlling an atomic layer etching process.

Another aspect of the present disclosure is to provide a method and apparatus for atomic layer etching capable of more freely increasing or reducing an etching amount in one cycle.

A further aspect of the present disclosure is to provide a method and apparatus for atomic layer etching capable of differently controlling an etching rate depending on a pattern position.

An atomic layer etching method according to an embodiment of the present disclosure is a method of etching an etching target film by sequentially performing a surface modification step and an etching step. The surface modification step includes a first plasma treatment step of treating a surface of the etching target film using ions of a first gas generated from plasma of the first gas, a second plasma treatment step of forming a surface modification layer on the surface of the etching target film using radicals of a second gas generated from plasma of the second gas, a precursor supply step of supplying a precursor to adsorb precursor molecules onto the surface of the etching target film having the surface modification layer formed thereon, and a third plasma treatment step of treating the surface of the etching target film having the surface modification layer formed thereon using ions of a third gas generated from plasma of the third gas. The etching step includes a heat treatment step of thermally treating a substrate having undergone the surface modification step to remove the surface modification layer from the etching target film and a cooling step of cooling the thermally treated substrate.

In an embodiment of the present disclosure, purge steps may be respectively performed between the second plasma treatment step and the precursor supply step and between the precursor supply step and the third plasma treatment step.

In an embodiment of the present disclosure, at least one of the first gas or the third gas may be an inert gas.

In an embodiment of the present disclosure, the first gas may be a gas reactive with the etching target film.

In an embodiment of the present disclosure, the third gas may be a gas reactive with the surface modification layer.

In an embodiment of the present disclosure, the plasma of the second gas may be remote plasma.

In an embodiment of the present disclosure, the first plasma treatment step may promote surface modification reaction of the etching target film by the radicals of the second gas in the second plasma treatment step.

In an embodiment of the present disclosure, in the heat treatment step, ligand exchange reaction may occur between the surface modification layer and the precursor molecules, and the third plasma treatment step may promote the ligand exchange reaction in the heat treatment step.

In an embodiment of the present disclosure, a cycle, including sequentially performing the surface modification step and the etching step once, may be repeated N times (N being an integer of 2 or greater).

In an embodiment of the present disclosure, in a predetermined one of the N cycles, at least one of the first plasma treatment step or the third plasma treatment step may not be performed.

In an embodiment of the present disclosure, the etching target film may be a film formed on a three-dimensional pattern including a pattern top surface and a pattern side surface, and an etching rate of the etching target film on the pattern top surface and an etching rate of the etching target film on the pattern side surface may be different from each other. For example, the etching rate of the etching target film on the pattern top surface may be greater than the etching rate of the etching target film on the pattern side surface.

In an embodiment of the present disclosure, a bias voltage may be applied to the etching target film in the first plasma treatment step or the third plasma treatment step.

An atomic layer etching method according to another embodiment of the present disclosure is a method of etching an etching target film by sequentially performing a surface modification step and an etching step. The surface modification step includes a surface modification layer formation step of forming a surface modification layer on a surface of the etching target film using radicals and a precursor supply step of supplying a precursor to adsorb precursor molecules onto the surface of the etching target film having the surface modification layer formed thereon. The etching step includes a heat treatment step of thermally treating a substrate having undergone the surface modification step to remove the surface modification layer from the etching target film and a cooling step of cooling the thermally treated substrate. The surface modification step further includes a plasma treatment step of treating the surface of the etching target film using ions in at least one of sections before the surface modification layer formation step and after the precursor supply step.

An atomic layer etching apparatus according to another aspect of the present disclosure includes a first process chamber configured to perform plasma treatment on a surface of an etching target film to form a surface modification layer on the etching target film and a controller. The first process chamber includes a chamber body having a processing space defined therein, a substrate support unit disposed inside the chamber body, the substrate support unit being configured to support a substrate having the etching target film formed thereon, a shower plate partitioning an internal space of the chamber body into an upper plasma generation space and a lower processing space, the shower plate including a plurality of through-holes, the shower plate being connected to ground, an upper plasma generation unit configured to generate plasma in the plasma generation space, a lower plasma generation unit configured to generate plasma in the processing space, and a gas supply unit configured to supply a gas to an interior of the chamber body. The controller is configured to perform a first plasma treatment step of treating the surface of the etching target film using ions of a first gas by controlling the gas supply unit and the lower plasma generation unit to generate plasma of the first gas in the processing space, a second plasma treatment step of forming the surface modification layer on the surface of the etching target film using radicals of a second gas supplied to the processing space through the plurality of through-holes by controlling the gas supply unit and the upper plasma generation unit to generate plasma of the second gas in the plasma generation space, a precursor supply step of adsorbing precursor molecules onto the surface of the etching target film having the surface modification layer formed thereon by controlling the gas supply unit to supply a precursor to the processing space, and a third plasma treatment step of treating the surface of the etching target film having the surface modification layer formed thereon using ions of a third gas by controlling the gas supply unit and the lower plasma generation unit to generate plasma of the third gas in the processing space.

The atomic layer etching apparatus according to an embodiment of the present disclosure may further include a second process chamber configured to perform a heat treatment process to remove the surface modification layer from the etching target film.

In an embodiment of the present disclosure, the second process chamber may include a chamber housing having a heat treatment space defined therein, a cooling unit disposed in the chamber housing, the cooling unit being configured to support the substrate having the etching target film formed thereon, and a heating unit disposed above the chamber housing, the heating unit being configured to thermally treat the substrate. When the substrate having undergone the third plasma treatment step is loaded into the chamber housing, the controller may perform a heat treatment step of removing the surface modification layer from the etching target film by controlling the heating unit to rapidly heat the substrate.

In an embodiment of the present disclosure, when the heat treatment step is completed, the controller may perform a cooling step of cooling the substrate by controlling the cooling unit.

In an embodiment of the present disclosure, the cooling unit may include a cooling plate including a coolant channel formed therein to allow a coolant to circulate therethrough and a plurality of lift pins configured to be movable upward and downward through a plurality of lift holes formed through the cooling plate. In the heat treatment step, the controller may move the plurality of lift pins upward to separate the substrate from the cooling plate, and in the cooling step, the controller may move the plurality of lift pins downward to bring the substrate into contact with the cooling plate.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a flowchart showing an atomic layer etching method according to an embodiment of the present disclosure;

FIG. 2 is a conceptual diagram showing the state of an etching target film during each step shown in FIG. 1;

FIG. 3 is a view showing an effect of the atomic layer etching method according to the embodiment of the present disclosure;

FIG. 4 is a view schematically showing the configuration of an atomic layer etching apparatus according to an embodiment of the present disclosure;

FIG. 5 is a view schematically showing a first process chamber according to an embodiment of the present disclosure; and

FIG. 6 is a view schematically showing a second process chamber according to an embodiment of the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

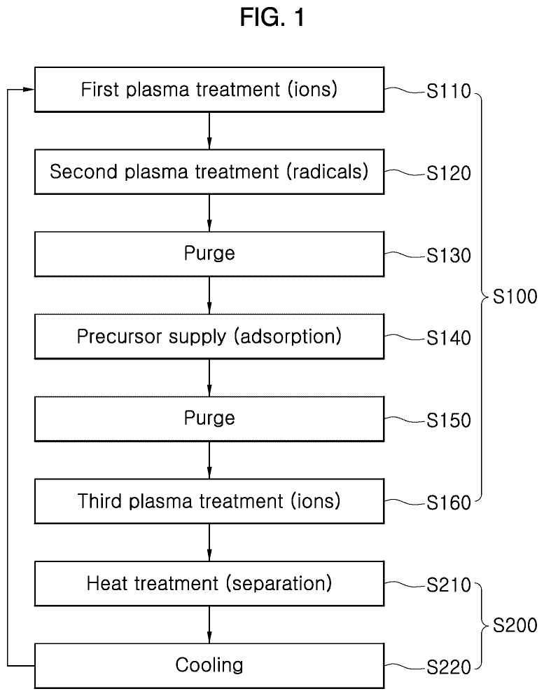

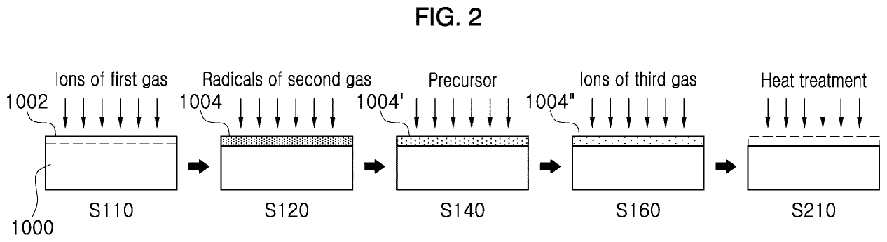

FIG. 1 is a flowchart showing an atomic layer etching method according to an embodiment of the present disclosure, and FIG. 2 is a conceptual diagram showing the state of an etching target film during each step shown in FIG. 1.

Referring to FIG. 1, the atomic layer etching method according to the embodiment of the present disclosure includes a surface modification step S100 and an etching step S200. The surface modification step S100 is a step of forming a surface modification layer on the surface of an etching target film, and the etching step S200 is a step of removing the surface modification layer from the etching target film.

The surface modification step S100 may include a first plasma treatment step S110, a second plasma treatment step S120, a precursor supply step S140, and a third plasma treatment step S160. Purge steps S130 and S150 may be included between the second plasma treatment step S120 and the precursor supply step S140 and between the precursor supply step S140 and the third plasma treatment step S160, respectively. In addition, the etching step S200 may include a heat treatment step S210 and a cooling step S220.

Hereinafter, the steps will be described with reference to FIGS. 1 and 2.

The first plasma treatment step S110 is a step of generating plasma of a first gas in a chamber in which a substrate having an etching target film 1000 formed thereon is disposed to treat the surface of the etching target film 1000 using ions (ions of the first gas) generated from the plasma of the first gas. The ions of the first gas are accelerated by a sheath voltage formed on the substrate surface in the plasma or by a separately applied bias voltage, and collide with the surface of the etching target film 1000. A predetermined amount of energy may be transferred to the etching target film 1000 by physical ion collision. The ion collision may cause a disturbance in the atomic-level crystal structure of the surface of the etching target film 1000. Compared to before the ion collision, a disturbed surface region may generate an ion collision region 1002 having several to several tens of atomic layers depending on the collision energy. The ion collision region 1002 may be a region in a relatively high-energy state compared to the surface of the etching target film 1000 before the ion collision.

The first gas may be an inert gas such as argon (Ar), but the present disclosure is not limited thereto. When the first gas is an inert gas, physical energy may be transferred to the surface of the etching target film 1000 by the ion collision in the first plasma treatment step S110. When the first gas is a gas reactive with the etching target film 1000, a predetermined chemical change may occur in the surface of the etching target film together with the transfer of physical energy thereto by the ion collision in the first plasma treatment step S110.

The second plasma treatment step S120 is a step of treating the surface of the etching target film 1000 using radicals (radicals of a second gas) generated from plasma of the second gas. The radicals of the second gas may be generated in a remote plasma region, and may then be delivered to the interior of the chamber in which the substrate is disposed. The radicals of the second gas may react with the etching target film 1000 to form a surface modification layer 1004 on the surface of the etching target film 1000.

The second gas may be selected depending on the type of etching target film. For example, when the etching target film is an aluminum oxide (Al₂O₃) film, the second gas may be a gas capable of generating fluorine (F) radicals. The second gas may be hydrogen fluoride (HF), and the radicals of the second gas may be fluorine radicals. The surface of the aluminum oxide film may be fluorinated by the fluorine radicals, and an aluminum fluoride (AlF₃) film may be formed as the surface modification layer 1004.

The surface modification reaction in the second plasma treatment step S120 (e.g., reaction in which the aluminum oxide film is fluorinated by fluorine radicals) may be affected by the ion collision region 1002. For example, the surface modification reaction may be further promoted by the ion collision region 1002. Because the ion collision region 1002 is a region in a relatively high-energy state, the ion collision region 1002 may relatively easily react with the radicals of the second gas. Therefore, compared to a case in which the first plasma treatment step S110 is not performed, the surface modification reaction may occur at a lower temperature, or a thicker surface modification layer 1004 may be formed at the same temperature.

After the second plasma treatment step S120, the purge step S130 may be performed to remove the second gas and/or reaction by-products from the chamber. The purge step S130 may be performed by supplying and exhausting an inert gas such as argon (Ar) to and from the chamber for a predetermined period of time.

After the purge step S130, the precursor supply step S140 may be performed. The precursor supply step S140 is a step of supplying a precursor to the chamber and adsorbing precursor molecules onto the surface of the etching target film 1000 on which the surface modification layer 1004 is formed. The precursor may be selected according to the surface modification layer 1004. For example, when the surface modification layer 1004 is an aluminum fluoride (AlF₃) film, the precursor may be trimethylaluminum (Al(CH₃)₃). In the embodiment of the present disclosure, the surface modification layer onto which the precursor is adsorbed is denoted as a surface modification layer 1004′ in order to distinguish the same from the surface modification layer 1004. The surface modification layer 1004′ may be removed from the surface of the etching target film 1000 by ligand exchange reaction in the subsequent etching step S200.

After the precursor supply step S140, the purge step S150 may be performed to discharge the precursor from the chamber. The purge step S150 may be performed by supplying and exhausting an inert gas such as argon (Ar) to and from the chamber for a predetermined period of time.

The third plasma treatment step S160 is a step of generating plasma of a third gas in the chamber to treat the surface of the surface modification layer 1004′ using ions (ions of the third gas) included in the plasma of the third gas. The ions of the third gas are accelerated by a sheath voltage formed on the substrate surface in the plasma or by a separately applied bias voltage, and collide with the surface of the surface modification layer 1004′. A predetermined amount of energy may be transferred to the surface modification layer 1004′ by physical ion collision.

The third gas may be the same gas as the first gas or may be a different gas from the first gas. The third gas may be an inert gas such as argon (Ar), but the present disclosure is not limited thereto. When the third gas is an inert gas, physical energy may be transferred to the surface of the surface modification layer 1004′ by the ion collision in the third plasma treatment step S160. When the third gas is a gas reactive with the surface modification layer 1004′, a predetermined chemical change may occur in the surface modification layer 1004′ together with the transfer of physical energy thereto by the ion collision in the third plasma treatment step S160.

The surface modification layer 1004′ may be changed to a surface modification layer 1004″ in a higher-energy state by the third plasma treatment step S160. The surface modification layer 1004″ may be in a higher-energy state than the surface modification layer 1004′, and may be more easily removed in the subsequent etching step S200. In particular, when a relatively thick surface modification layer is formed by performing the first plasma treatment step S110, performing the third plasma treatment step S160 may assist in cleanly removing the thick surface modification layer in the subsequent etching step S200.

The heat treatment step S210 is a step of heating the surface modification layer 1004″ to a high temperature to remove the same through ligand exchange reaction. Due to the high temperature, ligand exchange reaction may occur between the surface modification layer 1004 and the precursor molecules adsorbed thereon, and reaction products may be volatilized and discharged from the chamber, thereby removing the surface modification layer 1004″ from the etching target film 1000. The ligand exchange reaction may be determined depending on the surface modification layer 1004 and the type of precursor. For example, when the surface modification layer 1004 is an aluminum fluoride (AlF₃) film and the precursor is trimethylaluminum (Al(CH₃)₃), AlF(CH₃)₂ may be generated by ligand exchange reaction between AlF₃ and Al(CH₃)₃ and may be volatilized.

The heat treatment step S210 may be a rapid thermal annealing (RTA) step and may be a step of supplying heat using an infrared lamp.

After the heat treatment step S210, the cooling step S220 of cooling the substrate may be performed. The cooling step S220 may be performed by bringing the substrate into contact with a cooling plate through which a coolant flows.

The surface modification step S100 and the etching step S200 may be repeated multiple times. That is, after the cooling step S220, the substrate may return to the first plasma treatment step S110. When one sequential execution of the surface modification step S100 and the etching step S200 is defined as one cycle, a total of N cycles may be repeated until a target etching thickness is reached

Although the embodiment shown in FIGS. 1 and 2 has been described as performing both the first plasma treatment step S110 and the third plasma treatment step S160, the present disclosure is not limited thereto. In some cases, only the first plasma treatment step S110 may be performed, or only the third plasma treatment step S160 may be performed. Alternatively, in each of the cycles that are repeated multiple times, the first plasma treatment step S110 and the third plasma treatment step S160 may be selectively included. In this way, by selectively applying the first plasma treatment step S110 and the third plasma treatment step S160, the etching amount in one cycle may be more freely increased or reduced. That is, by applying the first plasma treatment step S110 and/or the third plasma treatment step S160, a larger amount of the etching target film may be etched in one cycle. Conversely, by omitting the first plasma treatment step S110 and/or the third plasma treatment step S160 in a specific cycle, the etching amount in the corresponding cycle may be reduced.

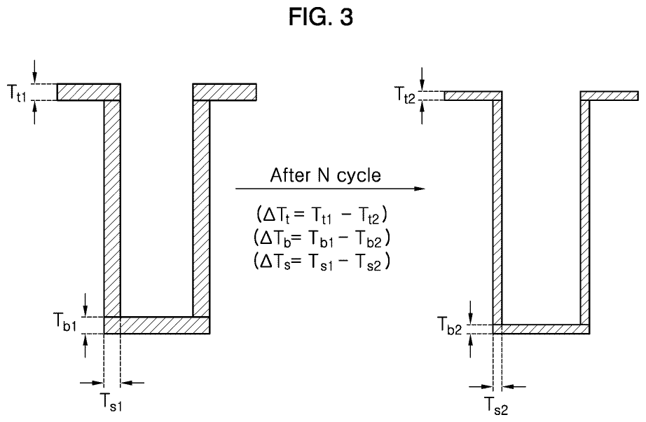

In addition, according to the embodiment of the present disclosure, the etching rate may be differently controlled depending on the pattern position. This will be described with reference to FIG. 3. FIG. 3 shows that the thickness of the etching target film 1000 deposited on a contact hole pattern having a high aspect ratio decreases after N cycles of the atomic layer etching process are performed on the etching target film 1000. The thickness of the etching target film formed on a top surface of the pattern before etching is Tt1, and the thickness after performing N cycles of the atomic layer etching process is Tt2. A thickness reduction (etching amount) of the etching target film on the upper surface of the pattern due to N cycles of the atomic layer etching process is ΔTt. The thickness of the etching target film formed on a bottom surface of the pattern before etching is Tb1, and the thickness after performing N cycles of the atomic layer etching process is Tb2. A thickness reduction (etching amount) of the etching target film on the bottom surface of the pattern due to N cycles of the atomic layer etching process is ΔTb. The thickness of the etching target film formed on a side surface of the pattern before etching is Ts1, and the thickness after performing N cycles of the atomic layer etching process is Ts2. A thickness reduction (etching amount) of the etching target film on the side surface of the pattern due to N cycles of the atomic layer etching process is ΔTs.

When the surface modification layer is formed using only radicals in the surface modification step, the etching amounts on the top surface, the bottom surface, and the side surface of the pattern may be substantially the same (ΔTt=ΔTb=ΔTs). In contrast, as in the embodiment of the present disclosure, when the first plasma treatment step S110 and/or the third plasma treatment step S160 is performed in the surface modification step S100, an amount of ion collision with the side surface of the pattern may be relatively small due to directionality of ions, and thus the etching amounts on the top and bottom surfaces of the pattern may be greater than that on the side surface of the pattern. This indicates that the etching rate on the side surface of a three-dimensional pattern may be controlled to be different from the etching rates on the top and bottom surfaces of the pattern. The difference between the etching rate on the side surface of the pattern and the etching rates on the top and bottom surfaces of the pattern may be more precisely controlled by applying a bias voltage in the first plasma treatment step S110 and/or the third plasma treatment step S160.

In addition, when a gas reactive with the etching target film, rather than an inert gas, is used as the first gas and/or the third gas, the etching rates on the top and bottom surfaces of the pattern may be controlled over a wider range. Depending on the type of the first gas and/or the third gas, reaction between radicals and the ion collision region 1002 may even be suppressed in the second plasma treatment step S120. In this case, the etching amounts on the top and bottom surfaces of the pattern may be less than that on the side surface of the pattern.

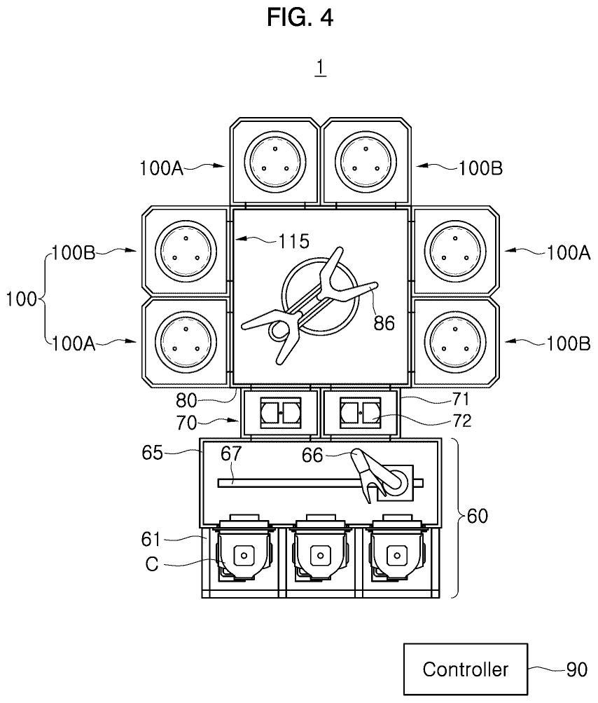

FIG. 4 is a view schematically showing the configuration of an atomic layer etching apparatus according to an embodiment of the present disclosure.

Referring to FIG. 4, the atomic layer etching apparatus 1 according to the embodiment of the present disclosure includes an index module 60, a load lock chamber 70, a transfer chamber 80, and a process chamber 100.

The index module 60 may be an equipment front end module (EFEM), and may include a load port 61 and an index frame 65.

A carrier C in which a substrate before or after processing is accommodated is provided at the load port 61. The carrier C may be a front opening unified pod (FOUP). A plurality of load ports 61 may be mounted in the index module 60.

The index frame 65 includes an index robot 66 that transfers a substrate between the carrier C seated on the load port 61 and the load lock chamber 70. The index frame 65 may be maintained in an atmospheric-pressure atmosphere.

The load lock chamber 70 is disposed between the index module 60 and the transfer chamber 80 to serve as a buffer. The load lock chamber 70 may include a buffer stage 72 inside a housing 71. The buffer stage 72 may provide a space in which an unprocessed substrate loaded into the load lock chamber 70 is temporarily held until the substrate is delivered to a transfer robot 86 in the transfer chamber 80, or a substrate delivered to the load lock chamber 70 by the transfer robot 86 after being processed in the process chamber 100 is temporarily held until the substrate is delivered to the index robot 66. The load lock chamber 70 may be switched between a reduced-pressure atmosphere and an atmospheric-pressure atmosphere. The load lock chamber 70 may be switched to an atmospheric-pressure atmosphere for substrate transfer with the index robot 66, and may be switched to a reduced-pressure atmosphere for substrate transfer with the transfer robot 86.

The transfer chamber 80 is maintained in a reduced-pressure atmosphere, and transfers a substrate between the load lock chamber 70 and the process chamber 100 using the transfer robot 86. The transfer robot 86 may be configured to perform horizontal, vertical, and rotational movements, and may serve to transfer an unprocessed substrate from the load lock chamber 70 to the process chamber 100 or to transfer a processed substrate from the process chamber 100 to the load lock chamber 70. The transfer robot 86 may include a plurality of robot arms to simultaneously transfer a plurality of substrates.

The transfer chamber 80 may be formed in a polygonal shape including a plurality of sides. Although the transfer chamber 80 is illustrated in FIG. 4 as having a rectangular shape, the present disclosure is not limited thereto. The number of sides of the transfer chamber 80 and the length of each side may be determined depending on various conditions, such as the number of process chambers 100 connected to the transfer chamber 80 and the footprint allowed for the atomic layer etching apparatus 1. Each side of the transfer chamber 80 is connected to the process chamber 100 or to the load lock chamber 70. The example shown in FIG. 4 is configured such that the transfer chamber 80 has a substantially rectangular shape, three sides of which are connected to the process chambers 100 and one side of which is connected to the load lock chamber 70.

The process chamber 100 provides a processing space in which the atomic layer etching process according to the embodiment of the present disclosure is performed, and a substrate loading/unloading port 115 is formed between the process chamber 100 and the transfer chamber 80. The substrate is transferred between the process chamber 100 and the transfer chamber 80 through the substrate loading/unloading port 115.

The process chamber 100 includes a first process chamber 100A and a second process chamber 100B. The surface modification step S100 may be performed in the first process chamber 100A, and the etching step S200 may be performed in the second process chamber 100B. In the first process chamber 100A, a plasma treatment process may be performed to form a surface modification layer on the surface of the etching target film. In the second process chamber 100B, a heat treatment process may be performed to remove the surface modification layer from the etching target film. The surface modification step S100 and the etching step S200 according to the embodiment of the present disclosure have been described with reference to FIGS. 1 and 2.

As shown in FIG. 4, one first process chamber 100A and one second process chamber 100B may be disposed on each of three sides of the transfer chamber 80. However, this is to be understood as an example. The number and/or arrangement of first process chambers 100A and second process chambers 100B included in the atomic layer etching apparatus 1 may be varied as needed. For example, when the etching process requires a longer processing time than the surface modification process, more second process chambers 100B may be disposed than the first process chambers 100A. Conversely, when the surface modification process requires a longer processing time than the etching process, more first process chambers 100A may be disposed than the second process chambers 100B. In addition, only the first process chambers 100A may be disposed on one side of the transfer chamber 80, and only the second process chambers 100B may be disposed on another side of the transfer chamber 80.

The controller 90 controls operation of the atomic layer etching apparatus 1. The controller 90 may include a central processing unit (CPU), memory, and circuits. The CPU may be one of any form of a general-purpose processor. The memory may be random access memory (RAM), read only memory (ROM), a floppy disk, a hard disk, or any other form of digital storage, local or remote. The memory may store a process recipe for performing the atomic layer etching process using the atomic layer etching apparatus. The controller 90 may control the atomic layer etching apparatus 1 so that the atomic layer etching process is performed on the etching target film according to the process recipe.

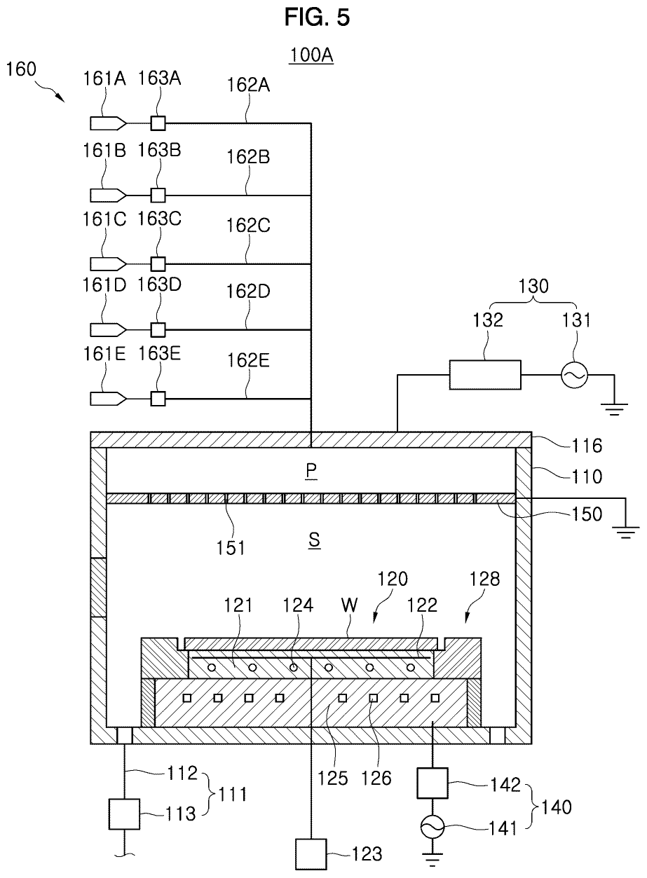

FIG. 5 is a view schematically showing the first process chamber 100A according to the embodiment of the present disclosure.

Referring to FIG. 5, the first process chamber 100A according to the embodiment of the present disclosure may include a chamber body 110, a substrate support unit 120, an upper plasma generation unit 130, a lower plasma generation unit 140, a shower plate 150, and a gas supply unit 160.

The first process chamber 100A includes the chamber body 110 having a processing space S defined therein. The chamber body 110 may be formed of a metal such as aluminum. The chamber body 110 is connected to an exhaust unit 111, which includes an exhaust pipe 112 and a vacuum pump 113, so that a vacuum is formed in the processing space S.

The substrate support unit 120 may be disposed inside the chamber body 110. The substrate support unit 120 supports a substrate W in the processing space S. The substrate W may be a semiconductor wafer. The substrate support unit 120 includes a dielectric plate 121 having a chuck electrode 122 embedded therein. The chuck electrode 122 may receive a voltage from a chuck power supply 123 to provide electrostatic adsorption force to the substrate W placed on an upper surface of the dielectric plate 121.

A base plate 125 may be disposed below the dielectric plate 121. The dielectric plate 121 and the base plate 125 may be bonded to each other using an adhesive layer (not shown). The base plate 125 may be made of a metal and may be grounded.

A ring member 128 is disposed to surround an outer periphery of the dielectric plate 121. The ring member 128 may include a focus ring.

The substrate support unit 120 may include a temperature control device for controlling the temperature of the substrate W. For example, the dielectric plate 121 may include a heater 124 for controlling the temperature of the substrate W. The heater 124 may be configured as a plurality of separated zone heaters in order to independently control the temperatures of respective regions of the substrate W. In addition, a coolant channel 126 for controlling the temperature of the substrate W may be defined inside the base plate 125. A low-temperature coolant, the temperature of which is adjusted by a chiller, may circulate through the coolant channel 126. The temperature of the substrate W may be controlled during the surface modification process by the heater 124 and/or the coolant channel 126.

Although the substrate support unit 120 has been described as being an electrostatic chuck with reference to FIG. 5, the present disclosure is not limited thereto.

The upper plasma generation unit 130 may include an upper radio-frequency (RF) power supply 131 and an upper matcher 132. The upper RF power supply 131 may supply an RF signal in a range of several MHz to several tens of MHz to an upper electrode 116 via the upper matcher 132. The upper electrode 116 may be disposed at a chamber cover portion of the chamber body 110. When RF power is supplied to the upper electrode 116 from the upper RF power supply 131, plasma may be generated in a plasma generation space P between the upper electrode 116 and the grounded shower plate 150. Among components of the plasma generated in the plasma generation space P, ions and electrons may be absorbed by the grounded shower plate 150, and only radicals may be supplied to the processing space S through through-holes 151 in the shower plate 150.

The lower plasma generation unit 140 may include a lower RF power supply 141 and a lower matcher 142. The lower RF power supply 141 may supply an RF signal in a range of several MHz to several tens of MHz to a lower electrode via the lower matcher 142. The lower electrode may be included in the base plate 125, or the base plate 125 may function as the lower electrode. When RF power is supplied to the lower electrode from the lower RF power supply 141, plasma may be generated in the processing space S between the lower electrode and the grounded shower plate 150. Ions included in the plasma generated in the processing space S may be accelerated toward the substrate W and may collide with the etching target film. Accordingly, the first plasma treatment step S110 and/or the third plasma treatment step S160 shown in FIG. 1 may be performed. Although not shown in FIG. 5, a separate bias power supply for ion acceleration may be provided. The bias power supply may be connected to the substrate support unit 120. The bias power supply may be a direct-current power supply.

The shower plate 150 may be disposed to partition the plasma generation space P and the processing space S from each other. The shower plate 150 may include a plurality of through-holes 151 formed therein. The shower plate 150 may be grounded to block ions and electrons in the plasma generation space P from moving to the processing space S, and may allow only radicals to be supplied to the processing space S through the through-holes 151.

The gas supply unit 160 may be configured to supply a gas to the interior of the chamber body 110, and may include a gas source 161, a gas supply pipe 162, and a flow controller 163. The gas source 161 may include a first gas source 161A configured to supply a first gas, a second gas source 161B configured to supply a second gas, a third gas source 161C configured to supply a third gas, a fourth gas source 161D configured to supply a precursor, and a fifth gas source 161E configured to supply a purge gas. Each of the gas sources 161A, 161B, 161C, 161D, and 161E may supply a gas through a corresponding one of gas supply pipes 162A, 162B, 162C, 162D, and 162E. Each of flow controllers 163A, 163B, 163C, 163D, and 163E may be mounted on a corresponding one of the gas supply pipes 162A, 162B, 162C, 162D, and 162E in order to control the flow rate of the supplied gas. The flow controller 163 may include a mass flow controller (MFC) and/or an on-off valve.

As shown in FIG. 5, five gas sources 161, five gas supply pipes 162, and five flow controllers 163 may be provided. However, this is to be understood as an example. The number of gas sources 161 may be varied depending on the types of gases required. For example, when argon (Ar) is used as the first gas, the third gas, and the purge gas, the first gas source 161A, the third gas source 161C, and the fifth gas source 161E may be integrated into a single gas source.

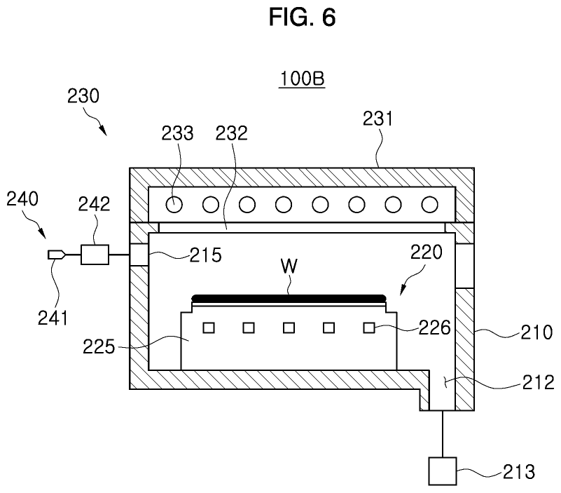

FIG. 6 is a view schematically showing the second process chamber 100B according to the embodiment of the present disclosure.

Referring to FIG. 6, the second process chamber 100B may include a chamber housing 210, a cooling unit 220, and a heating unit 230.

The chamber housing 210 may provide a heat treatment space for the substrate W. The chamber housing 210 may be formed of a metal such as aluminum. The chamber housing 210 may be connected to an exhaust unit 211 including an exhaust pipe 212 and a vacuum pump 213.

A cooling unit 220 may be disposed in the chamber housing 210. The cooling unit 220 may include a cooling plate 225 having a coolant channel 226 formed therein to allow a coolant to circulate therethrough, and may cool the substrate W placed on an upper surface of the cooling plate 225. Although not shown, the cooling plate 225 includes a plurality of lift holes formed therethrough, and lift pins move upward and downward through the lift holes while supporting the substrate W. When heat treatment is performed on the substrate W, the lift pins may move upward to separate the substrate W from the upper surface of the cooling plate 225, and when the substrate W is cooled after heat treatment, the lift pins may move downward to place the substrate W on the upper surface of the cooling plate 225.

A heating unit 230 for thermally treating the substrate W may be provided above the chamber housing 210. The heating unit 230 may include a cover 231 and a heating lamp 233. The heating lamp 233 may be an infrared lamp. A window 232 may be disposed below the heating lamp 233. The window 232 may serve to protect the heating lamp 233 from deposition of etching by-products generated during the process. For example, the window 232 may be a dielectric window. The window 232 may transmit light generated by the heating lamp 233 to supply thermal energy to the substrate W.

The second process chamber 100B of the present disclosure configured as described above may be a rapid thermal process (RTP) apparatus. In addition, the heating unit 230 provided in the second process chamber 100B is not limited to the infrared lamp, and may include any other heat treatment device capable of performing a rapid thermal process. For example, the heating unit 230 may include a microwave generator or a laser generator.

The gas supply unit 240 may include a gas source 241 and a flow controller 242, and may supply a purge gas for purging the heat treatment space. The supplied purge gas may be introduced into the heat treatment space through a gas supply port 215, and may then be discharged to the outside through the exhaust pipe 212. The atmosphere in the heat treatment space during the heat treatment process may be adjusted by the gas supply unit 240, or the gas supply unit 240 may not supply the gas during the heat treatment process.

Hereinafter, the operation of the atomic layer etching apparatus 1 controlled by the controller 90 will be described.

When the carrier C accommodating a substrate W on which an etching target film 1000 is formed is placed on the load port 61, the controller 90 controls the index robot 66 to unload the substrate W from the carrier C and to transfer the substrate W to the load lock chamber 70. When the pressure in the load lock chamber 70 is sufficiently reduced, the controller 90 controls the transfer robot 86 to load the substrate W into the first process chamber 100A. When the substrate W is placed on the substrate support unit 120 of the first process chamber 100A, the controller 90 controls the first process chamber 100A such that the first plasma treatment step S110, the second plasma treatment step S120, the purge step S130, the precursor supply step S140, the purge step S150, and the third plasma treatment step S160 shown in FIG. 1 proceed sequentially.

In detail, the controller 90 may control the first gas source 161A to supply the first gas to the processing space S, and may control the lower plasma generation unit 140 to generate plasma of the first gas in the processing space S, thereby performing the first plasma treatment step S110 of treating the etching target film 1000 using ions of the first gas.

Subsequently, the controller 90 may control the second gas source 161B to supply the second gas to the plasma generation space P, and may control the upper plasma generation unit 130 to generate plasma of the second gas in the plasma generation space P, thereby performing the second plasma treatment step S120 of treating the etching target film 1000 using radicals of the second gas to form the surface modification layer 1004.

Subsequently, the controller 90 may control the fifth gas source 161E to supply the purge gas to the processing space S, thereby performing the purge step S130.

Subsequently, the controller 90 may control the fourth gas source 161D to supply the precursor to the processing space S, thereby performing the precursor supply step S140 of adsorbing the precursor onto the surface of the etching target film 1000.

Subsequently, the controller 90 may control the fifth gas source 161E to supply the purge gas to the processing space S, thereby performing the purge step S150.

Subsequently, the controller 90 may control the third gas source 161C to supply the third gas to the processing space S, and may control the lower plasma generation unit 140 to generate plasma of the third gas in the processing space S, thereby performing the third plasma treatment step S160 of treating the etching target film 1000 using ions of the third gas.

When the surface modification step S100 is completed in this sequence, the controller 90 may control the transfer robot 86 to unload the substrate W from the first process chamber 100A and to load the substrate W into the second process chamber 100B, and may then perform the etching step S200.

When the substrate W is loaded into the second process chamber 100B, the controller 90 may control the heating unit 230 to rapidly heat the substrate W, thereby performing the heat treatment step S210 of removing the surface modification layer from the etching target film 1000. In this case, the controller 90 may perform control such that the heat treatment step S210 proceeds in a state in which the lift pins (not shown) are moved upward to separate the substrate W from the cooling plate 225.

When the heat treatment step S210 is completed, the controller 90 may perform control such that the substrate W is placed on the cooling plate 225 and is held for a predetermined period of time, thereby performing the cooling step S220. In this case, the controller 90 may perform control such that the cooling step 220 proceeds in a state in which the lift pins (not shown) are moved downward to bring the substrate W into contact with the cooling plate 225.

When the cooling step S220 is completed, the controller 90 may control the transfer robot 86 to transfer the substrate W back to the first process chamber 100A so that the process is repeated from the surface modification step S100. After a predetermined number of cycles is completed, the controller 90 may control the transfer robot 86 and the index robot 66 to return the substrate W having undergone etching to the carrier C.

As is apparent from the above description, according to the method and apparatus for atomic layer etching according to the embodiment of the present disclosure, an etching target film may be treated using ions before and/or after formation of a surface modification layer using radicals, thereby more precisely controlling an atomic layer etching process.

According to the method and apparatus for atomic layer etching according to the embodiment of the present disclosure, the thickness of the surface modification layer and/or an etching rate in an etching step may be varied depending on treatment of the etching target film using ions, thereby more freely increasing or reducing an etching amount in one cycle.

According to the method and apparatus for atomic layer etching according to the embodiment of the present disclosure, a degree of treatment using ions may be varied depending on a pattern position due to directionality of ions, thereby differently controlling an etching rate depending on the pattern position.

Although the exemplary embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. An atomic layer etching method of etching an etching target film by sequentially performing a surface modification step and an etching step,
wherein the surface modification step comprises:
a first plasma treatment step of treating a surface of the etching target film using ions of a first gas generated from plasma of the first gas;
a second plasma treatment step of forming a surface modification layer on the surface of the etching target film using radicals of a second gas generated from plasma of the second gas;
a precursor supply step of supplying a precursor to adsorb precursor molecules onto the surface of the etching target film having the surface modification layer formed thereon; and
a third plasma treatment step of treating the surface of the etching target film having the surface modification layer formed thereon using ions of a third gas generated from plasma of the third gas, and
wherein the etching step comprises:
a heat treatment step of thermally treating a substrate having undergone the surface modification step to remove the surface modification layer from the etching target film; and
a cooling step of cooling the thermally treated substrate.

2. The atomic layer etching method as claimed in claim 1,
wherein the surface modification step further comprises:
purge steps are respectively performed between the second plasma treatment step and the precursor supply step and between the precursor supply step and the third plasma treatment step.

3. The atomic layer etching method as claimed in claim 1,
wherein at least one of the first gas and the third gas is an inert gas.

4. The atomic layer etching method as claimed in claim 1,
wherein the first gas is a gas reactive with the etching target film.

5. The atomic layer etching method as claimed in claim 1,
wherein the third gas is a gas reactive with the surface modification layer.

6. The atomic layer etching method as claimed in claim 1,
wherein the plasma of the second gas is remote plasma.

7. The atomic layer etching method as claimed in claim 1,
wherein the first plasma treatment step promotes surface modification reaction of the etching target film by the radicals of the second gas in the second plasma treatment step.

8. The atomic layer etching method as claimed in claim 1,
wherein, in the heat treatment step, ligand exchange reaction occurs between the surface modification layer and the precursor molecules, and
wherein the third plasma treatment step promotes the ligand exchange reaction in the heat treatment step.

9. The atomic layer etching method as claimed in claim 1,
wherein one cycle comprises sequentially performing the surface modification step and the etching step, and
wherein the cycle is repeated N times, N being an integer of 2 or greater.

10. The atomic layer etching method as claimed in claim 9,
wherein, in a predetermined one of the N cycles, at least one of the first plasma treatment step and the third plasma treatment step is not performed.

11. The atomic layer etching method as claimed in claim 1,
wherein the etching target film is a film formed on a three-dimensional pattern including a pattern top surface and a pattern side surface, and
wherein an etching rate of the etching target film on the pattern top surface and an etching rate of the etching target film on the pattern side surface are different from each other.

12. The atomic layer etching method as claimed in claim 11,
wherein the etching rate of the etching target film on the pattern top surface is greater than the etching rate of the etching target film on the pattern side surface.

13. The atomic layer etching method as claimed in claim 1,
wherein a bias voltage is applied to the etching target film in the first plasma treatment step or the third plasma treatment step.

14. An atomic layer etching method of etching an etching target film by sequentially performing a surface modification step and an etching step,
wherein the surface modification step comprises:
a surface modification layer formation step of forming a surface modification layer on a surface of the etching target film using radicals; and
a precursor supply step of supplying a precursor to adsorb precursor molecules onto the surface of the etching target film having the surface modification layer formed thereon,
wherein the etching step comprises:
a heat treatment step of thermally treating a substrate having undergone the surface modification step to remove the surface modification layer from the etching target film; and
a cooling step of cooling the thermally treated substrate, and
wherein the surface modification step further comprises a plasma treatment step of treating the surface of the etching target film using ions in at least one of sections before the surface modification layer formation step and after the precursor supply step.

15. The atomic layer etching method as claimed in claim 14,
wherein the etching target film is a film formed on a three-dimensional pattern including a pattern top surface and a pattern side surface, and
wherein an etching rate of the etching target film on the pattern top surface and an etching rate of the etching target film on the pattern side surface are different from each other.

16. An atomic layer etching apparatus comprising:
a first process chamber configured to perform plasma treatment on a surface of an etching target film to form a surface modification layer on the etching target film; and
a controller operatively coupled to the first process chamber,
wherein the first process chamber comprises:
a chamber body having a processing space defined therein;
a substrate support unit disposed inside the chamber body, the substrate support unit being configured to support a substrate having the etching target film formed thereon;
a shower plate partitioning an internal space of the chamber body into an upper plasma generation space and a lower processing space, the shower plate including a plurality of through-holes, the shower plate being connected to ground;
an upper plasma generation unit configured to generate plasma in the plasma generation space;
a lower plasma generation unit configured to generate plasma in the processing space; and
a gas supply unit configured to supply a gas to an interior of the chamber body, and
wherein the controller is configured to perform:
a first plasma treatment step of treating the surface of the etching target film using ions of a first gas by controlling the gas supply unit and the lower plasma generation unit to generate plasma of the first gas in the processing space;
a second plasma treatment step of forming the surface modification layer on the surface of the etching target film using radicals of a second gas supplied to the processing space through the plurality of through-holes by controlling the gas supply unit and the upper plasma generation unit to generate plasma of the second gas in the plasma generation space;
a precursor supply step of adsorbing precursor molecules onto the surface of the etching target film having the surface modification layer formed thereon by controlling the gas supply unit to supply a precursor to the processing space; and
a third plasma treatment step of treating the surface of the etching target film having the surface modification layer formed thereon using ions of a third gas by controlling the gas supply unit and the lower plasma generation unit to generate plasma of the third gas in the processing space.

17. The atomic layer etching apparatus as claimed in claim 16, further comprising a second process chamber configured to perform a heat treatment process to remove the surface modification layer from the etching target film.

18. The atomic layer etching apparatus as claimed in claim 17,
wherein the second process chamber comprises:
a chamber housing having a heat treatment space defined therein;
a cooling unit disposed in the chamber housing, the cooling unit being configured to support the substrate having the etching target film formed thereon; and
a heating unit disposed above the chamber housing, the heating unit being configured to thermally treat the substrate, and
wherein, when the substrate having undergone the third plasma treatment step is loaded into the chamber housing, the controller performs a heat treatment step of removing the surface modification layer from the etching target film by controlling the heating unit to rapidly heat the substrate.

19. The atomic layer etching apparatus as claimed in claim 18,
wherein, when the heat treatment step is completed, the controller performs a cooling step of cooling the substrate by controlling the cooling unit.

20. The atomic layer etching apparatus as claimed in claim 19, wherein the cooling unit comprises:
a cooling plate including a coolant channel formed therein to allow a coolant to circulate therethrough; and
a plurality of lift pins configured to be movable upward and downward through a plurality of lift holes formed through the cooling plate,
wherein, in the heat treatment step, the controller moves the plurality of lift pins upward to separate the substrate from the cooling plate, and
wherein, in the cooling step, the controller moves the plurality of lift pins downward to bring the substrate into contact with the cooling plate.
